(19) United States
(12) Patent Application Publication
(10) Pub. No.: US 2021/0337637 A1
(43) Pub. Date: Oct. 28, 2021

(54) Blower Style Magnetic Induction Cogeneration Assembly for Generating Heat And/Or Electricity and Incorporating Traditional Heating Elements Along With Heat Sink Ribs for Redirecting Fluid Flow

(71) Applicant: Heat X, LLC, Auburn Hills, MI (US)

(72) Inventor: Miguel A. Linares, Bloomfield Hills, MI (US)

(73) Assignee: Heat X, LLC, Auburn Hills, MI (US)

(21) Appl. No.: 17/238,427

(22) Filed: Apr. 23, 2021

Related U.S. Application Data
(60) Provisional application No. 63/014,234, filed on Apr. 23, 2020.
(60) Provisional application No. 63/022,002, filed on May 8, 2020.

(51) Int. Cl. H05B 6/10; H02K 7/18; H01L 35/30; F03D 3/04

(52) U.S. Cl. CPC H05B 6/108; H02K 7/183; F05B 2220/706; F03D 3/0409; H01L 35/30

(57) ABSTRACT

A fluid conditioning assembly having a body constructed of an insulating material. An inner housing is configured within the body defining a spiral passageway in communication with an inlet for redirecting a fluid flow through an outlet. A shaft extends within the body and rotatably supports a conductive and fluid redirecting plate or like component positioned within the inner housing. At least one magnet or electromagnet is positioned within the inner housing in proximity to the rotating component, causing thermal conditioning of the fluid flow resulting from creation of high frequency oscillating magnetic fields at a given frequency range, the thermally conditioned fluid flow being redirected through the outlet. Additional features include the ability to generate electricity in a cogeneration application of the assembly. Conventional elements can also be incorporated into the assembly for operating simultaneously or being deactivated/turned off after an initial startup period.

### CROSS REFERENCE TO RELATED APPLICATIONS

The present application claims the priority of U.S. Ser. No. 63/014,234 filed Apr. 23, 2020. The present application also claims the priority of U.S. Ser. No. 63/022,002 filed May 8, 2020.

### FIELD OF THE INVENTION

The present invention relates generally to a magnetocaloric/magnetic or electromagnetic induction furnace/heater. More specifically, the present invention discloses a magnetic or electromagnet blower style assembly which provides either of heating or air circulation modes and, in a separate variant, provides in combination electrical generating (or cogeneration) capabilities. The present invention also discloses a variety of thermally conditioning or heating assemblies, not limited to any of the magnetic, electromagnet or induction variety, and utilizing either of internal or external mounted motors or other rotary inducing inputs, these in combination with other variants incorporating induction coils for transmitting a current flow into magnetic flux inducing eddy currents within a magnetically conductive material.

### BACKGROUND OF THE INVENTION

The phenomena of magnetocaloric/magnetic or electromagnetic induction heating is well known in the prior art by which heat is generated in an electrically conductive object by the generation of eddy currents, also called Joule heating. The typical induction heater includes an electronic oscillator which passes a high frequency alternating current through an electromagnet. The eddy currents flowing through the resistance of a conductive material placed in proximity to the magnet/electromagnet in turn heat it. Put another way, the eddy currents result in a high-frequency oscillating magnetic field which causes the magnet's polarity to switch back and forth at a high-enough rate to produce heat as byproduct of friction.

One known example of a prior art induction heating system is taught by the electromagnetic induction air heater of Garza, US 2011/0215089, which includes a conductive element, a driver coupled to the conductive element, an induction element positioned close to the conductive element, and a power supply coupled to the induction element and the driver. Specifically, the driver applies an angular velocity to the rotate the conductive element around a rotational axis. The power supply provides electric current to the induction element to generate a magnetic field about the induction element such that the conductive element heats as it rotates within the magnetic field to transfer heat to warm the cold fluid flow streams. The fluid flow streams are circulated about the surface of the conductive element and directed by the moving conductive element to generate warm fluid flow streams from the conductive element.

Also referenced is the centrifugal magnetic heating device of Hsu 2013/0062340 which teaches a power receiving mechanism and a heat generator. The power receiving mechanism further includes a vane set and a transmission module. The heat generator connected with the transmission module further includes a centrifugal mechanism connected to the transmission module, a plurality of bases furnished on the centrifugal mechanism, a plurality of magnets furnished on the bases individually, and at least one conductive member corresponding in positions to the magnets. The vane set is driven by nature flows so as to drives the bases synchronically with the magnets through the transmission module, such that the magnets can rotate relative to the conductive member and thereby cause the conductive member to generate heat.

The phenomena of magnetocaloric/magnetic or electromagnetic induction heating is well known in the prior art by which heat is generated in an electrically conductive object by the generation of eddy currents, also called Joule heating. The typical induction heater includes an electronic oscillator which passes a high frequency alternating current through an electromagnet. The eddy currents flowing through the resistance of a conductive material placed in proximity to the magnet/electromagnet in turn heat it. Put another way, the eddy currents result in a high-frequency oscillating magnetic field which causes the magnet's polarity to switch back and forth at a high-enough rate to produce heat as byproduct of friction.

One known example of a prior art induction heating system is taught by the electromagnetic induction air heater of Garza, US 2011/0215089, which includes a conductive element, a driver coupled to the conductive element, an induction element positioned close to the conductive element, and a power supply coupled to the induction element and the driver. Specifically, the driver applies an angular velocity to the rotate the conductive element around a rotational axis. The power supply provides electric current to the induction element to generate a magnetic field about the induction element such that the conductive element heats as it rotates within the magnetic field to transfer heat to warm the cold fluid flow streams. The fluid flow streams are circulated about the surface of the conductive element and directed by the moving conductive element to generate warm fluid flow streams from the conductive element.

Also referenced is the centrifugal magnetic heating device of Hsu 2013/0062340 which teaches a power receiving mechanism and a heat generator. The power receiving mechanism further includes a vane set and a transmission module. The heat generator connected with the transmission module further includes a centrifugal mechanism connected to the transmission module, a plurality of bases furnished on the centrifugal mechanism, a plurality of magnets furnished on the bases individually, and at least one conductive member corresponding in positions to the magnets. The vane set is driven by nature flows so as to drives the bases synchronically with the magnets through the transmission module, such that the magnets can rotate relative to the conductive member and thereby cause the conductive member to generate heat.

Additional references in the known art are applied to cooktop or other surface heating applications, among these the assembly of US 2020/0072472 to Kim having a case, a cover plate coupled to an upper end of the case and including an upper plate configured to seat an object on an upper surface of the upper plate. A working coil disposed in the case is configured to heat the object. A thin film is attached on the upper plate and a thermal insulating member is disposed vertically between a lower surface of the upper plate and the working coil.

Nam, US 2019/0289678 teaches a method of operating an induction cooktop appliance including supplying a power signal to an induction heating element of the appliance in response to a request received via a user input of the appliance. Other references of note include the induction stirring apparatus for a cooktop disclosed in US 2017/0202059 of Stoufer.

### SUMMARY OF THE PRESENT INVENTION

The present invention discloses, in a first embodiment, a fluid conditioning assembly having a body constructed of an insulating material. An inner housing is located within the body and defines a spiral passageway in communication with an inlet for redirecting a fluid flow through an outlet. The inner housing can include any suitable metal or alloy, ceramic or any metal-ceramic composite material or graphite or any combination of such materials.

A shaft extends within the body and rotatably supports a conductive and fluid redirecting plate or like component positioned within the inner housing. At least one magnet or electromagnet is positioned within the inner housing in proximity to the rotating conductive component, causing thermal conditioning of the fluid flow from creation of, at a given frequency, oscillating magnetic fields, the thermally conditioned fluid flow being redirected through the outlet.

The fluid redirecting component further includes a magnetocaloric or thermally conductive material. The fluid redirecting component further includes a disk-shaped element having a first inner plurality of circumferentially arrayed vanes and a second outer plurality of circumferentially arrayed vanes. The inlet further exhibits multiple inlet locations configured along at least one of a side or forward-facing surface of the body, with the outlet configured on a forward facing surface of the body.

Additional features include the magnet/electromagnet further exhibiting a plurality of magnets/electromagnets which are supported upon a plate located within the inner housing, with the plate being laterally displaceable along the shaft between an extended position in proximity to the rotating conductive plate for generating inductive heating and a retracted position spaced away from the rotating plate in an ambient air circulation mode. A motor or other rotary inducing input is provided for driving the shaft. The motor or other rotary inducing input is located at any interior or exterior position relative to the body.

Other features include thermal sink pins incorporated into each of opposite and outer facing sides of the inner housing and extending to inside wall surfaces of the body in order to draw outwardly emanating heat from the sides of the body interior, through the walls of the inside housing and toward its spiral extending interior. One or more conventional heating elements are integrated into the body surrounding the inner housing for assisting initial heat up of the conductive material. The conventional heating elements can include any of a resistor coil, electromagnetic induction component or electronic wave heating component. A controller is provided for deactivating the conventional element after a start-up period of time once the thermally conditioned air or fluid has reached a certain temperature threshold.

Rotational electric generating components surround the rotating shaft for generating electricity in a cogeneration application of the assembly. Alternatively, solid state thermoelectric generator devices are located upon the inner housing for converting temperature differences resulting from, at a given frequency, oscillating fields into electrical energy in a cogeneration application of the assembly.

In additional variants, the present invention discloses a variety of fluid conditioning assemblies, in each instance having a body constructed of an insulating material. In one non-limiting embodiment, the fluid conditioning assembly is provided in the form of a furnace/heater having an insulating body, within which is supported an inner housing defining a spiral passageway in communication with an inlet for redirecting a fluid flow through an outlet. The inner housing can again include any suitable metal or alloy, ceramic or any metal-ceramic composite material or graphite or combination of such conductive materials.

A sub-variant of the furnace/heater includes an externally supported motor or other rotary inducing input with a shaft extending within the body and rotatably supports a conductive and fluid redirecting plate or like component positioned within the inner housing. At least one magnet or electromagnet is positioned within the inner housing in proximity to the rotating conductive component, resulting in thermal conditioning of the fluid flow from the creation of oscillating magnetic fields at a given frequency range, the thermally conditioned fluid flow being redirected through the outlet. A further sub-variant teaches the magnets/electromagnets being substituted by an arrangement of induction coils and associated controllers for generating the necessary magnetocaloric effect.

The fluid redirecting component further includes a magnetocaloric or thermally conductive material and may further include a disk-shaped element having a first inner plurality of circumferentially arrayed vanes and a second outer plurality of circumferentially arrayed vanes. Baffles can be incorporated into an outer annular region of the inner housing for facilitating redirection of air movement for facilitating a more balanced air exhaust profile. The body can further exhibit multiple inlet locations configured along at least one of a side or forward-facing surface of the body, with the outlet configured on a forward facing surface of the body.

In a further variant, the external motor or other rotary inducing input is substituted by an internal motor or other rotary inducing input incorporated into the furnace/heater body. In alternating sub-variants, the internal motor or other rotary inducing input can be combined with either of an arrangement of induction coils or proximately located magnets/electromagnets which can be stationary positioned in proximity to the rotating conductive plate.

Any of the variants of furnace/heater can also include thermal sink pins incorporated into each of opposite and outer facing sides of the inner housing and extending to inside wall surfaces of the body in order to draw outwardly emanating heat from the sides of the body interior, through the walls of the inside housing and toward its spiral extending interior. One or more conventional heating elements are integrated into the body surrounding the inner housing for assisting initial heat up of the conductive material. The conventional heating elements can include any of a resistor coil, electromagnetic induction component or electronic wave heating component. A controller is provided for deactivating the conventional element after a start-up period of time once the thermally conditioned air or fluid has reached a certain temperature threshold.

Also provided are rotational spiral airflow redirecting and/or electric generating components for generating electricity in a cogeneration application of the assembly. Alternatively, solid state thermoelectric generator devices are located upon the inner housing for converting temperature differences resulting from the oscillation of magnetic fields at a given frequency range into electrical energy in a cogeneration application of the assembly. This can further include providing thermoelectric generators placed within the interior walls of the inner housing or any other locations, and with any electric power (wattage) produced by the thermoelectric generators or rotationally electric generating components being redirected to the motor or other rotary inducing input in order to reduce operating costs.

### BRIEF DESCRIPTION OF THE DRAWINGS

Reference will now be made to the attached drawings, when read in combination with the following detailed description, wherein like reference numerals refer to like parts throughout the several views, and in which:

FIG. 1 a perspective view of the magnetocaloric/magnetic or electromagnet induction furnace/heater or a magnetocaloric heat pump assembly according to a first embodiment of the present invention for providing either of heating or air circulation modes;

FIG. 2 is a cutaway view of FIG. 1 and depicting each of the inner housing incorporating a spiral configured interior passageway for collecting and redirecting a fluid flow for exhaust through a forward directed outlet, as well as a central rotatable conductive fan component actuated by a motor or other rotary inducing input and sandwiched between the walls of the inner housing, a proximately located magnet/electromagnet supporting plate displacing between an extended and induction heating mode and a laterally retracted and non-heating air circulation mode;

FIG. 3 is a further enlargement of FIG. 2 and better depicting the inner and outer circumferential fluid flow redirecting vane profiles associated with the rotatable component, along with the provision of the thermal sink pins incorporated into each of opposite sides of the fixed inner housing in order to draw outwardly emanating heat from the sides of the body inwardly toward its central core, as well as depicting conventional heating elements, such as resistor coils, which are integrated into the housing in perimeter extending fashion around the central rotating component and the proximately located magnetic/electromagnetic plate to provide faster thermal conditioning of the conductive materials across which the fluid flow is directed;

FIG. 4 is a further radial cutaway with part of the outer housing removed and better showing the configuration of the thermal heat sink pins for drawing heat back toward the spiral shaped inner fluid passageway of the assembly as well as depicting the recess passageways within the housing for directing the fluid flow as well as for seating the conventional heating coils;

FIG. 5 is an illustration similar to FIG. 1 of a variant of the assembly of FIG. 1 and depicting each of both outer perimeter arranged intake and outlet fluid flow passageways associated with the housing, as well as a side extending shaft for operating the magnet/electromagnet plate and surrounding fixed mounts for supporting a motor or other rotary inducing input on an exterior side of the housing in contrast to the interior mounting motor or other rotary inducing input arrangement of FIG. 1;

FIG. 6 is an end plan view of the central rotating plate with outer conductive plates including heat sink pins for drawing heat inwardly toward the spiraling core passageway for communicating the fluid flow, the magnetic/electromagnet supporting plate depicted in FIG. 3 being obscured from view;

FIG. 7 is a rotated and downwardly looking perspective of a selected outer conductive plate and depicting both the arrangement of the heat sink pins along with the central support location for receiving the rotatable driving shaft associated with the magnetic/electromagnetic plate;

FIG. 8 is a downwardly looking plan view of FIG. 7;

FIG. 9 is an illustration of a central rotating plate forming a portion of the present assembly, such integrating dual pluralities of inner and outer radially spaced, arcuate shaped and circumferentially extending vanes;

FIG. 10 is a reverse side view of the rotating plate of FIG. 9;

FIG. 11 is a perspective view of the magnetocaloric/magnetic or electromagnet induction furnace/heater or magnetocaloric heat pump assembly according to a second embodiment the present invention for providing either of heating or air circulation modes;

FIG. 12 is a cutaway view of the embodiment of FIG. 11 and depicting each of the inner housing incorporating a spiral configured interior passageway for collecting and redirecting a fluid flow for exhaust through a forward directed outlet, as well as a central rotatable conductive fan component of larger scale than correspondingly shown in the variant of FIG. 2 and actuated by a motor or other rotary inducing input, the rotating component sandwiched between the walls of the inner housing, with a proximately located magnet/electromagnet supporting plate displacing between an extended and induction heating mode and a laterally retracted and non-heating air circulation mode;

FIG. 13 is a slightly rotated view of FIG. 12 and better showing the features of the provision of the thermal sink pins incorporated into each of opposite sides of the fixed inner housing in order to draw outwardly emanating heat from the sides of the body inwardly toward its central core, as well as depicting conventional heating elements, such as resistor coils, which are integrated into the housing in perimeter extending fashion around the central rotating component and the proximately located magnetic/electromagnetic plate to provide faster thermal conditioning of the conductive materials across which the fluid flow is directed, additional features including air redirection baffles for encouraging interior spiral fluid flow as well as any of thermal electric generators or rotational electric generators for electrical cogeneration capabilities;

FIG. 14 is a perspective view of the lengthened outer circumferential plurality of vanes of the widened rotating conductive component;

FIG. 15 is a subset assembly view of the rotating component of FIG. 14 in combination with a fixed supporting component of the inner housing;

FIG. 16 is a cutaway view of a magnetic induction or magnetocaloric assembly according to a further variant and depicting an insulating outer body incorporating each of an inner housing having spiral configured interior passageway for collecting and redirecting a fluid flow for exhaust through a forward directed outlet, as well as a central rotatable conductive component actuated by a motor or other rotary inducing input in rotating fashion between the walls of the inner housing, one or more magnets/electromagnets incorporated into an interior of the inner housing proximate the central rotating component, as well as depicting conventional heating elements, such as resistor coils, which are integrated into the housing in perimeter extending fashion around the central rotating component and the proximately located magnetic/electromagnetic plate to provide faster thermal conditioning of the conductive materials across which the fluid flow is directed, thermal heat sink pins drawing heat back toward the spiral shaped inner fluid passageway of the assembly as well as depicting the recess passageways within the housing for directing the fluid flow as well as for seating the conventional heating coils, and airflow redirecting elements including baffles or other fluid redirecting components being incorporated into an arcuately extending inner end cap surface of the inner housing defining the spiral passageway and operating to influence the fluid flow along the spiral passageway toward the outlet;

FIG. 17 is a variant to the assembly of FIG. 16 and substituting the magnets/electromagnets in favor of induction coils and coil controllers for providing thermal conditioning the fluid through the assembly;

FIG. 18 is a further subset variant of FIG. 17 and by which an internal motor or other rotary inducing input construction substitutes for the external motor or other rotary inducing input, this in combination with the induction heating coils and associated controllers;

FIG. 19 is an internal motor or other rotary inducing input reconfiguration of the assembly of FIG. 16 with the interior positioned magnets/electromagnets;

FIG. 20 is a sectional perspective of a side wall portion of the spiral passageway inner housing of any of FIGS. 16-19 and depicting each of the central rotating component with inner and outer pluralities of circumferentially directed vanes along with baffles placed in the outer annular fluid chamber for redirecting air/fluid movement to facilitate a more balanced exhaust pattern, as well as again showing the wind generators placed in any or all of the baffles or walls of the inner housing;

FIG. 21 is a similar illustration to FIG. 20 and further depicting an arrangement of thermoelectric generators incorporated into the interior recessed walls of the inner housing plates for providing cogeneration capabilities to the thermally conditioning assembly; and

FIG. 22 is an enlarged lower partial cutaway perspective of the assembly in FIG. 5 and better depicting the features of air/fluid intake and exhaust ports of the inner housing in combination with a variant of the thermoelectric cogeneration components and rotary fluid flow generating/redirection components for redirecting electric power (wattage) produced by the generators into the input electric power (wattage) for driving the motor or other rotary inducing component in order to reduce operating costs for the overall assembly.

### DETAILED DESCRIPTION OF THE PREFERRED EMBODIMENTS

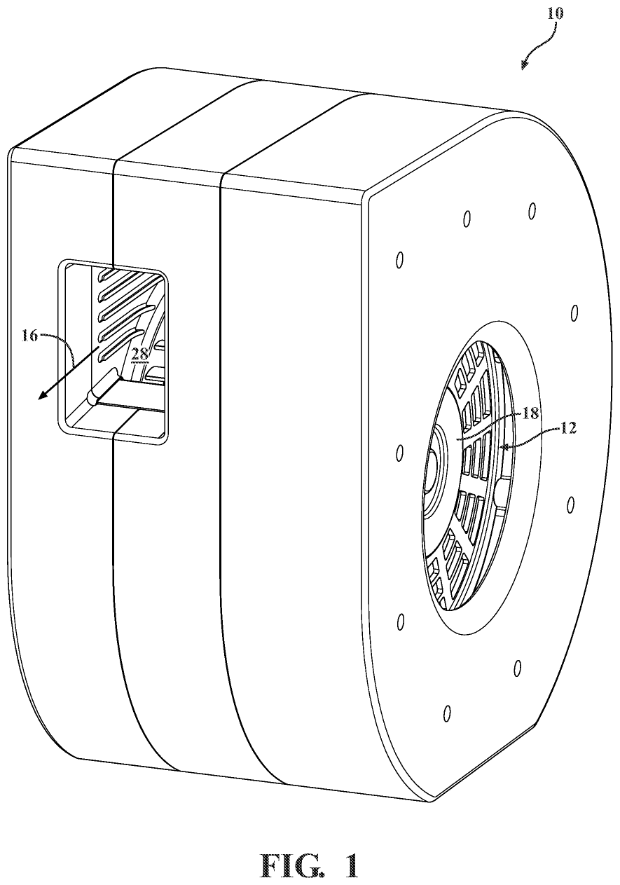

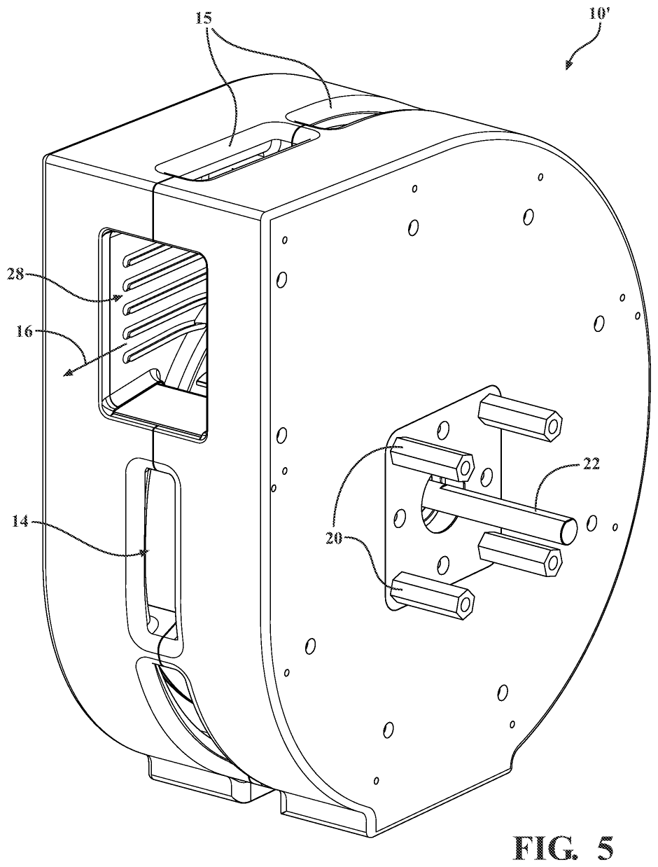

With reference to the attached illustrations, the present invention discloses a magnetocaloric/magnetic or electromagnetic induction furnace/heater or magnetocaloric heat pump, this generally shown by three dimensional shaped body 10 in FIG. 1 as well as 10′ in FIG. 5. More specifically, the present invention discloses a magnetic or electromagnet blower style assembly which provides either of heating or air circulation modes in combination with electrical generating (or cogeneration) capabilities.

Either body 10 (three tier stackable in FIG. 1) or 10′ (two tier stackable in FIG. 5) includes one or more fluid inlet locations which can include being located at an open side location (see at 12 in FIGS. 1-3) or, alternately or additionally, at a forward facing location 14 or outer side annular locations 15 (see in FIG. 5). A fluid outlet is further located at 16 in each of the three dimensional bodies 10/10′ depicted in FIGS. 1 and 5. As further shown, the body can be constructed of any suitable insulating material and can exhibit without limitation a three dimensional radial shape (not limited to a blower style arrangement) with the curved forward facing location incorporating any of the selected inlets 14/15 and outlet 16.

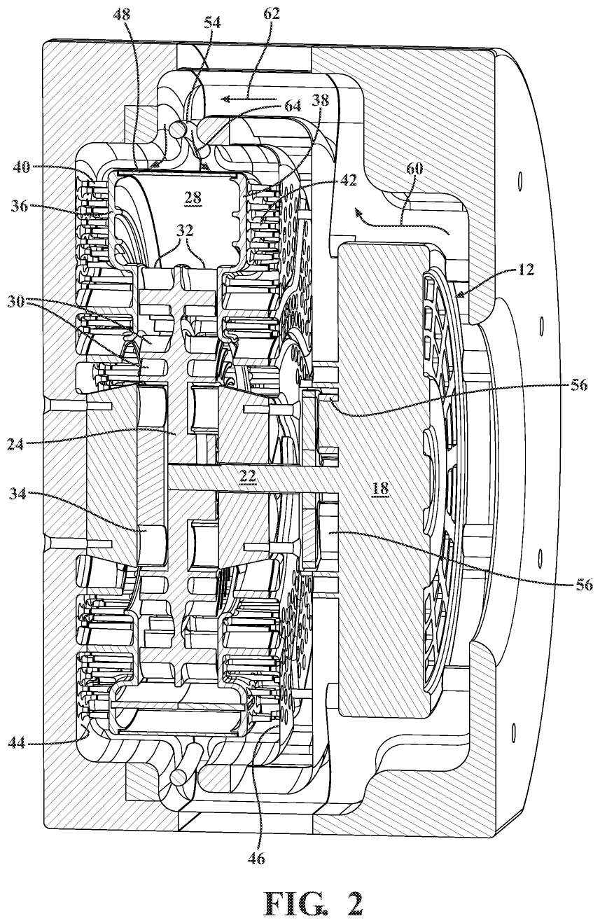

Referring to FIGS. 2-4 in succession, a motor or other rotatory inducing input 18 is situated in proximity to the circular shaped side opening 12 in the body 10. In contrast, FIG. 5 depicts an exterior arrangement of fixed mounts (see at 20) extending from a side exterior of the body 10′. In either instance, the internal or external mounted motor or other rotary inducing input 18 or other rotatable input operates a shaft 22 (shown in either FIGS. 2 and 5) which extends within the body and which in turn supports a conductive and fluid redirecting component 24.

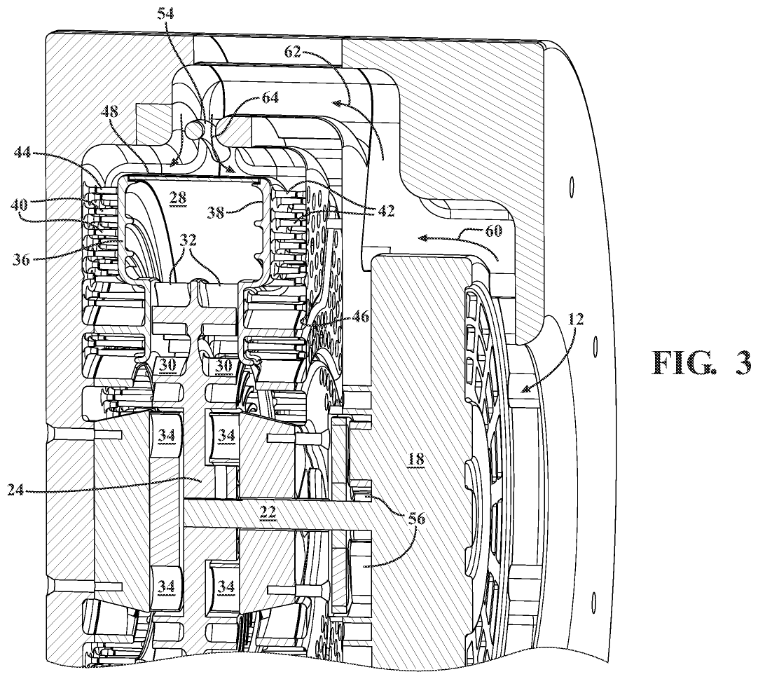

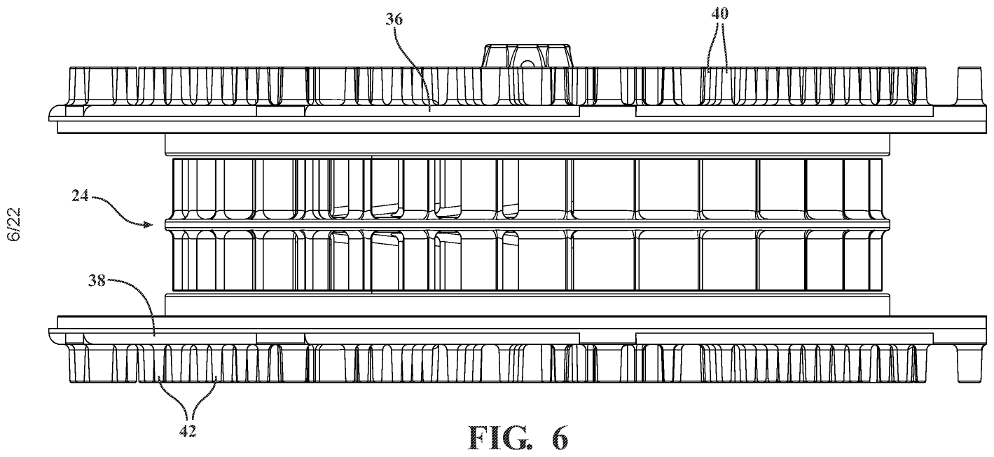

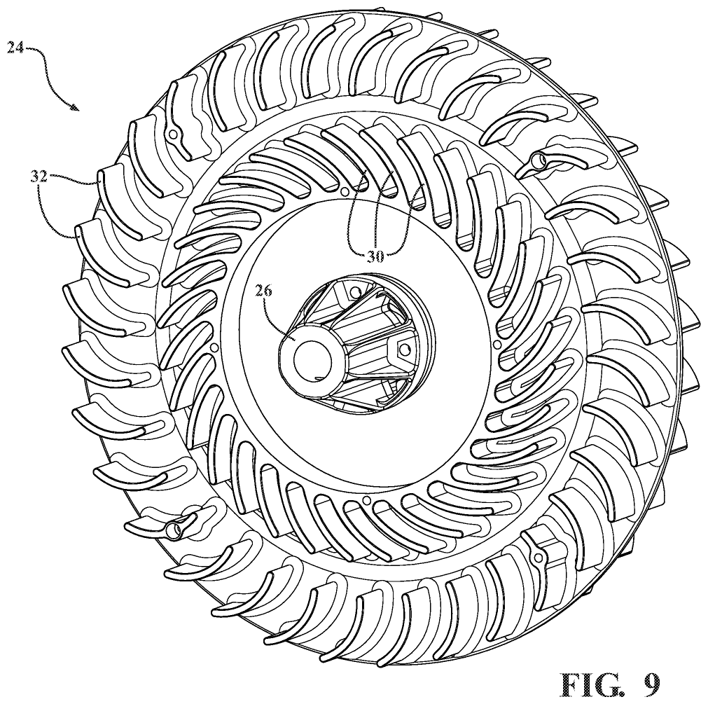

With additional reference to FIGS. 6, 9 and 10 the rotating/redirecting component 24 can be constructed of any conductive or magnetocaloric material and includes a central reinforced aperture support location 26 (see in FIG. 9) for mounting to an end location of the shaft 22 (see also FIGS. 2-3) and so that the rotating component 24 is supported within an inner housing structure defining a spiral configured interior passageway (see at 28 in FIGS. 1 and 3-5) for collecting and redirecting the fluid flow between the inlet 12 (see FIG. 1-3) or 14 (FIG. 5) and outlet 16 locations.

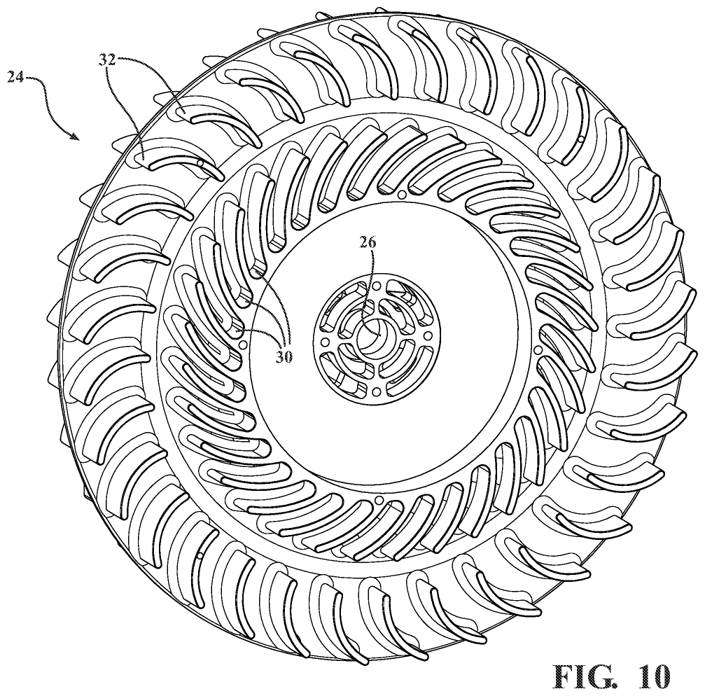

The rotating conductive component 24 is typically a conductive and fluid directing disk shaped plate or like component having inner 30 and outer 32 arcuate and segmented pluralities of fluid flow redirecting vanes extending from each of opposite surfaces of the component 24 (see as best shown in FIGS. 9-10) and about both of inner and outer circumferences of the component. As further shown, the respective inner 30 and outer 32 radial spaced pluralities of vanes can be arranged so that their arcuate profiles are opposing one another, this assisting in baffling or slowing of the outwardly directed fluid flows in order to maximize their thermal conditioning profiles.

As further best shown in FIG. 3, either of magnets or electromagnets can be supported at any location within the body (these represented by inner arcuate pockets 34 within which the magnets/electromagnets are seated or otherwise affixed). The magnets/electromagnets can be located either inside or outside of the inner housing and preferably in proximity to the rotating conductive component. The magnets/electromagnets 34, in one non-limiting arrangement shown in FIGS. 2-3, are positioned within a stationary interior of the inner housing, and about which the rotating conductive component 24 is supported and, in response to rotation of the outer component 24 in proximity to the magnets/electromagnets, results in the thermal conditioning of the fluid flow resulting from the creation of the oscillating magnetic fields at a given frequency range, with the thermally conditioned fluid flow being redirected through the outlet 16.

Additional variants of the present invention also contemplate the magnets/electromagnets 34 being reconfigured onto a separate plate and which are again either positioned stationary or rotatable relative to the conductive fan component 24. This can also include relocating (although not being shown) the magnets/electromagnets to a separate plate or like support which can be positioned about the shaft 22, and which is displaceable between each of an extended position in which the magnets/electromagnets are disposed in proximity to the rotating conductive plate or component and a retracted position in which the magnets/electromagnets are displaced laterally away from the rotating component in a further non-thermally conditioning air circulation mode.

Alternatively, or in combination to displacing laterally away from the magnets/electromagnets, magnetic shielding can be accomplished by sliding or rotating a spacer with one layer or multiple layers of one or multiple magnetic shielding materials with high magnetic permeability and with high magnetic saturation. Ferromagnetic metals such as steels or MuMetal, an industry reference material defined in Milspec 14411C. Also, and in the instance of electromagnets, these can be deactivated or turned off in a further non-thermally conditioning air circulation mode.

The present invention further contemplates other configurations for supporting any arrangement of magnets/electromagnets within either of the inner housing, the central interior rotating conductive component, or any position between, in order to provide the desired thermal conditioning properties. This can also include other ways of shielding the magnets and which can include turning off in the instance of using electromagnets. As further previously described, electromagnetic shielding is the practice of reducing the electromagnetic field in a space by blocking the field with barriers made of conductive or magnetic materials.

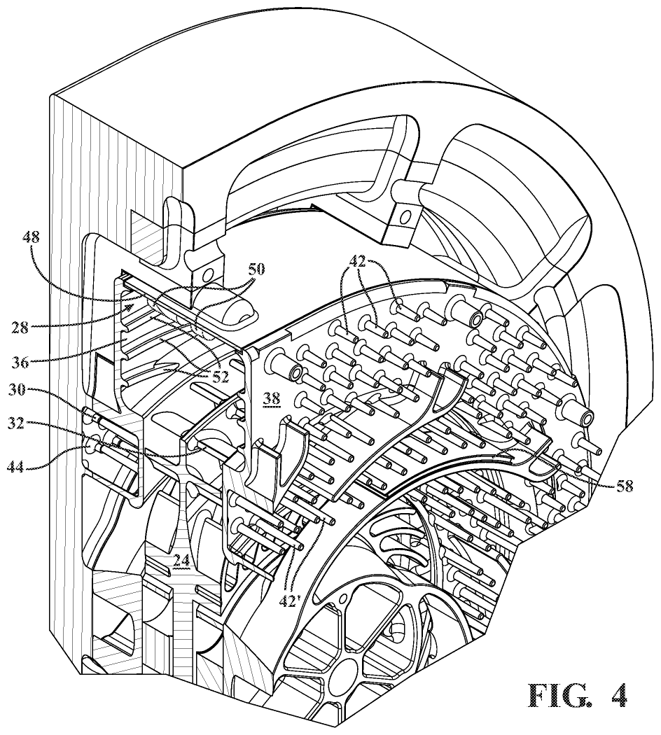

With reference again to FIGS. 2-4, the inner housing of the body for creating the spiral inner passageway further includes a pair of side plates 36 and 38 which are secured within an open interior cavity of the body and so that pluralities of thermal sink pins, see at 40 and 42, respectively, are incorporated into each of opposite and outer facing sides of the inner housing and respectively extend to inside wall surfaces (at 44 and 46 in FIGS. 2-4), this in order to draw outwardly emanating heat from the sides of the body back through the walls of the plates 36/38 and into the spiral interior passageway 28 in order to optimize redirection of thermal flow by the inner 30 and outer 32 plurality of vanes through the outlet 16. As further best shown in FIG. 4, the thermal sink pins can include different sizes or configurations (see further at 42′) depending upon their location on the exterior of the side plates.

As best depicted in FIGS. 2-4, the spiral extending inner housing is shown in cutaway in an outer radial and surrounding the shaft supported and rotating conductive component 24 and includes an outer end cap 48 which mates with outer edges of the side plates or walls 36/38 walls. The inner housing plates 36/38 and end cap 48 can, without limitation, be constructed of any suitable metal or alloy, ceramic or any metal-ceramic composite material or graphite or any combination of such materials which, in combination with the central rotating conductive component 24, provides any degree of thermal conductivity.

Additional features include the provision of airflow redirecting elements (at 50 in FIG. 4), these including baffles or other fluid redirecting components incorporated into the arcuately extending inner end cap surface 48 of the inner housing defining the spiral passageway and which operates to influence the fluid flow along the spiral passageway toward the outlet. The inside surfaces of the side plates 36/38 can also each include arcuate side passageway projections, best shown at 52 for side plate 36 in FIG. 4, to further assist in maintaining continuous fluid flow redirection along the spiral extending passageway interior of the inner housing toward the outlet 16.

Additional features include conventional heating elements 54 (see as best shown in FIG. 3), such as resistor coils, electromagnetic induction components or electronic wave heating components as shown in FIGS. 2-3 and which can be integrated into the housing in perimeter extending fashion around the magnetic/electromagnetic rotating plate or component 24 and the outer sandwiching conductive plates 36/38, this in order to provide faster thermal conditioning of the conductive materials across which the fluid flow is directed. The conventional heating elements are usually deactivated or turned off after an initial start-up period has passed, typically indicative of the inductive or magneto-caloric material having achieved desired thermally conditioned (heat up or cooled) properties.

Other features include the provision of coils or other thermal electric generating components surrounding a rotating shaft for generating electricity as a further cogeneration application of the assembly. This can include rotational electric generating components shown at 56 in FIGS. 2-3 surrounding the rotating shaft for generating electricity in a cogeneration application of the assembly. Additionally or alternately, and referring to FIG. 4, solid state thermoelectric generator devices 58 can be located upon the inner housing for converting temperature differences resulting from the oscillating magnetic fields into electrical energy in a cogeneration application of the assembly.

In this fashion, intake air 12 is pre-heated within the body interior, along passageways 60, 62 and 64 depicted in FIGS. 2-3, and resulting from passage in proximity to the motor or other rotary inducing input 18. At this point, the main inductive heating occurs at the core interface of the rotating conductive component or plate 24 (where the magnets or electromagnets 34 are situated) relative to the surrounding inner housing plates 36/38, with the thermal conditioned flow then being directed by the vanes 30/32 of the rotating plate 24 through the forward outlet 16.

Without limitation, the configuration and material selection for each of the plates 34/36 are such that they can be selected from any conductive materials which can include varying patterns of materials, bi-materials or multi-materials designs, such including any of metals or alloys, ceramics or any metal ceramic composite materials with ferromagnetic, ferromagnetic, antiferromagnetic, paramagnetic or diamagnetic properties. As understood, the plates possess properties necessary to generate adequate oscillating magnetic fields for inducing magnetic heating, such again resulting from the ability to either maintain or switch the magnet polarity at a sufficiently high rate in order for the generated friction to create the desired heat/cold profile.

Without limitation, conductive material(s) incorporated into the assembly can include varying patterns of materials, bi-materials or multi-material designs, such including any of metals or alloys, ceramics or any metal ceramic composite materials with ferromagnetic, ferrimagnetic, antiferromagnetic, paramagnetic or diamagnetic properties and, as understood, do not generate magnetic fields but are based on electromagnetic or magnetic induction such that they create eddy currents to allow for the frictional generation of heat in proximity to the interface between the rotating central component 24 and the surrounding plates 36/38 and end cap 48 defining the inner spiral extending passageway.

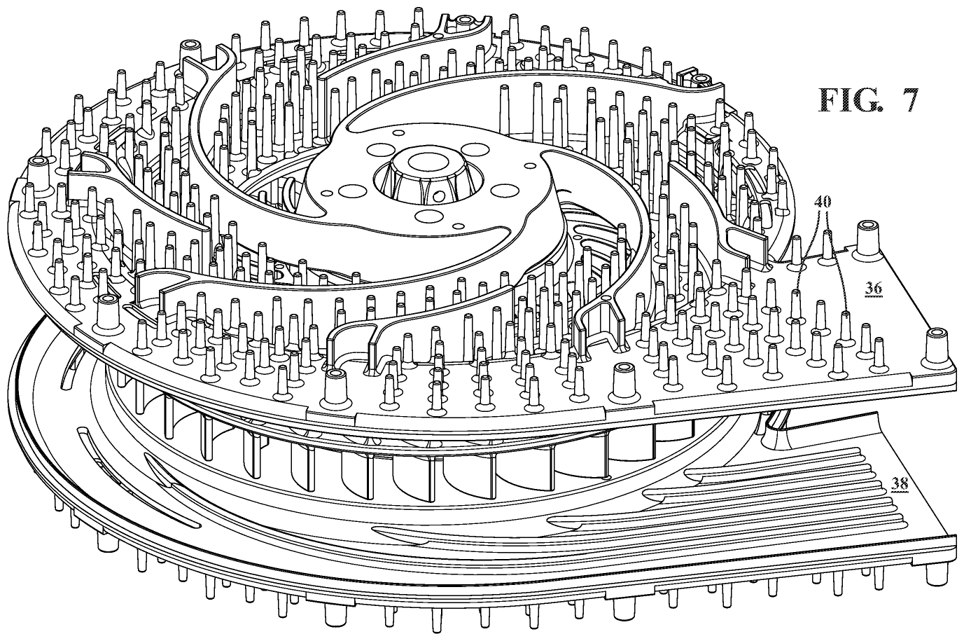

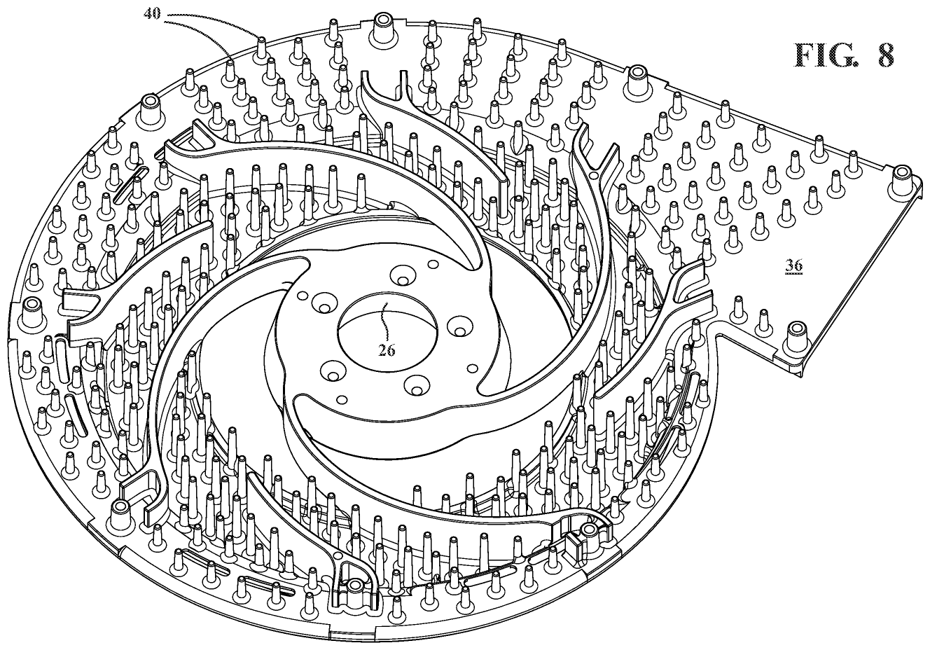

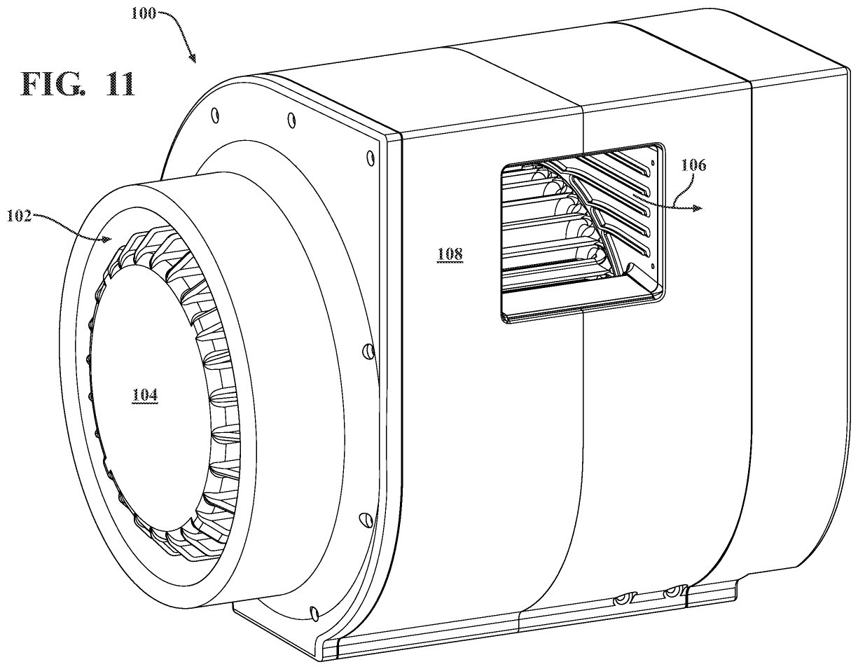

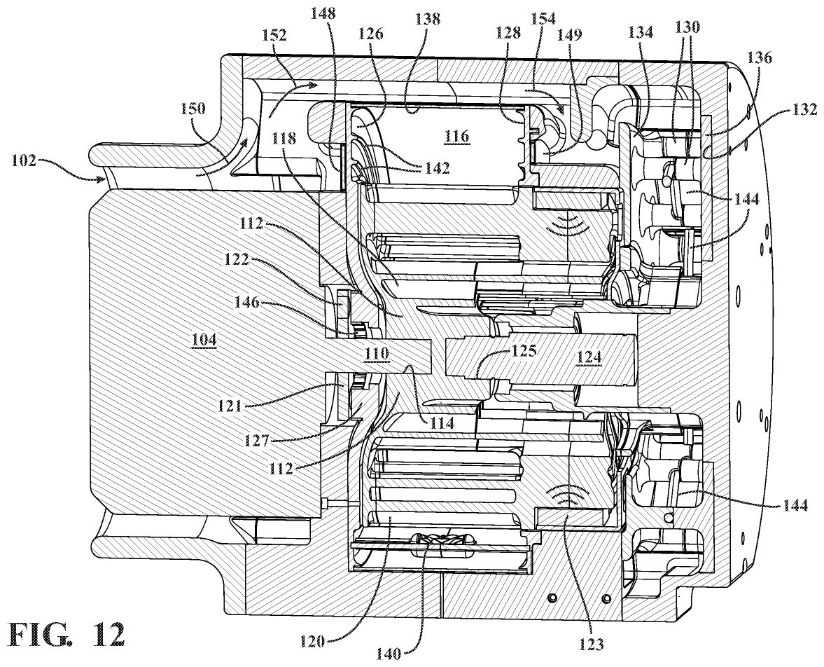

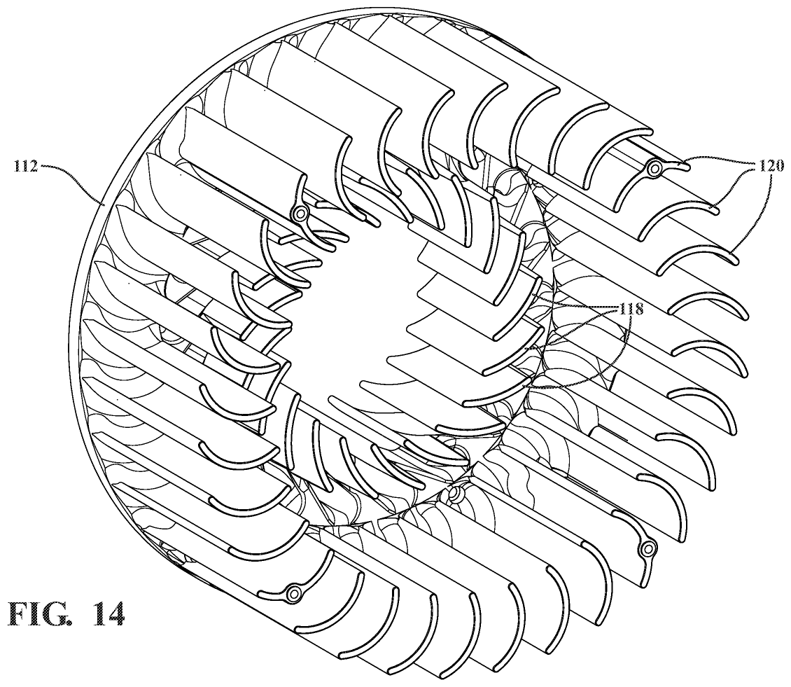

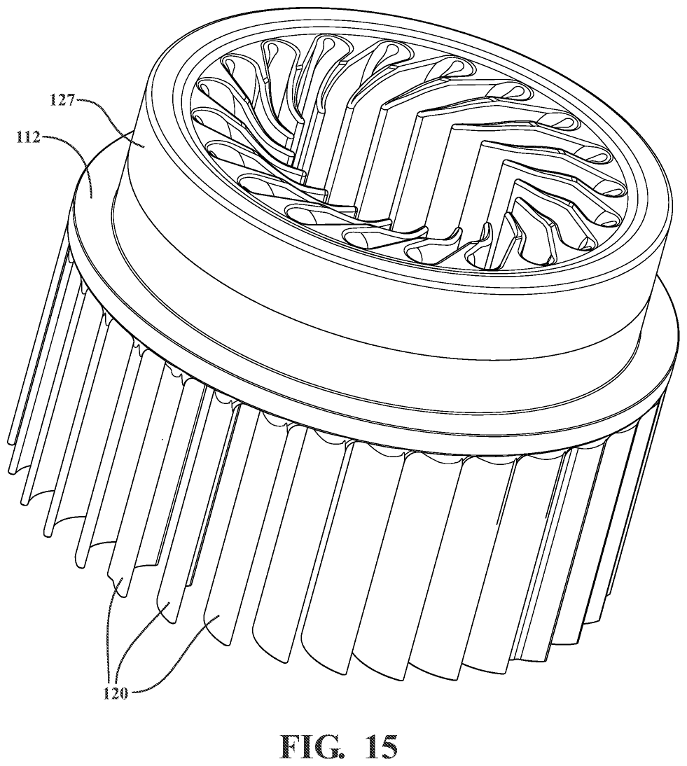

Proceeding now to FIG. 11, a perspective view is generally shown at 100 of the magnetic or electromagnet induction furnace/heater or a magnetocaloric heat pump assembly according to a second embodiment of the present invention for providing either of heating or air circulation modes. As will be described with reference to the succeeding views FIGS. 12-15, the variant 100 is similar in overall construction and operation to that depicted at 10 in FIGS. 1-10, except as to scale and such as by which the variant of FIGS. 11, et seq. can be configured to provide either of heat and/or electrical output which is generally double that of the initial variant. In either version, the furnace/heater can be stackable so as to include any number of modules which can include separate magnet/electromagnet supporting plates and which can be selectively or cooperatively driven by the associated driving shaft according to any scale of operation.

As with the initial embodiment 10, the body 100 includes one or more fluid inlet locations which can include (as depicted in FIGS. 11-13) being located at an open side location 102, such as in proximity to an internally mounted motor or other rotary inducing input 104 or other rotatable input. Although not shown, the three dimensional and insulated body depicted in FIG. 11 can include additional intake apertures at other locations not limited to being located upon the forward face as depicted in subset variant 10′ in FIG. 5.

A fluid outlet is further located at 106 in the three-dimensional body depicted in FIG. 11. As previously described, the body can be constructed of any suitable insulating material and can exhibit without limitation a three-dimensional radial shape with the curved intermediate extending portion with a further flattened forward facing location 108 (see FIG. 11).

As is depicted in each of FIGS. 11-13 in succession, a motor or other rotary inducing input 104 is situated in proximity to the circular shaped side opening 102 in the body 100. As disclosed in the preceding embodiment, the variant 100 also envisions an exterior arrangement of fixed mounts (such as previously depicted at 20 in FIG. 5) which can extend from a side exterior of the body 100. In either instance, the internal or external mounted motor or other rotary inducing input 104 or other rotatable input operates a shaft 110 which extends within the body and which in turn supports a conductive and fluid redirecting component 112.

With additional reference to FIGS. 12-15, the rotating/redirecting component 112 can exhibit a widened drum shape compared to that depicted at 24 in the initial embodiment and can further again be constructed of any conductive or magnetocaloric material and including a central reinforced aperture support location 114 (see FIG. 12) for mounting to an end location of the shaft 110 and so that the rotating component 112 is supported within an inner housing structure defining a spiral configured interior passageway (see at 116) for collecting and redirecting the fluid flow between the inlet 102 and outlet 106 locations.

The rotating conductive and fluid redirecting plate or like component 112, similar to that previously depicted at 24, again includes a conductive-disk shaped component having inner 118 and outer 120 arcuate and segmented pluralities of fluid flow redirecting vanes extending from each of opposite surfaces of the component 112 and about both of inner and outer circumferences of the component 112. As further shown, the respective inner 118 and outer 120 radial spaced pluralities of vanes can, similar to that depicted at 30 and 32 in the rotating component 24 of the initial variant, be arranged so that their arcuate profiles are opposing one another, this assisting in baffling or slowing of the outwardly directed fluid flows in order to maximize their thermal conditioning profiles.

Similar to that previously depicted at 34 in FIG. 3, either of magnets or electromagnets (see at 122 in FIG. 12 integrated into magnetic plate) can be supported within the body in proximity to the inner housing and rotating conductive component 112 and, in response to rotation of the component 112 results in a magnetic flux causing the thermal conditioning of the fluid flow resulting from the creation of the oscillating magnetic fields at a given frequency range, with the thermally conditioned fluid flow being redirected through the outlet 106.

A magnetic plate 121 is located between the motor or other rotary inducing input 104 or other rotatable input and an opposing side wall location associated with a reinforced central region of a selected inner housing plate (see at 127 as below described) of the inner housing. Any plurality of magnets or electromagnets 122 are configured within the plate 121 and so that, upon rotation of the drum shaped component 112, thermal conditioning occurs. The heating created by the magnets 122 assists in cogeneration capabilities in reference to the elements 146 described below.

As previously stated, the magnets/electromagnets are stationary mounted in the instance of air heating variants. That said, the magnetic/electromagnetic plates can also be redesigned to rotate in other fluid or surface heating applications. In such additional variants, the magnet/electromagnetic plate 121 can be designed according to other non-limiting variants so as to be axially retracted or disconnected from the rotating shaft and rendered stationary in a non-thermal conditioning application of the fluid flow, such as in an ambient conditioning mode.

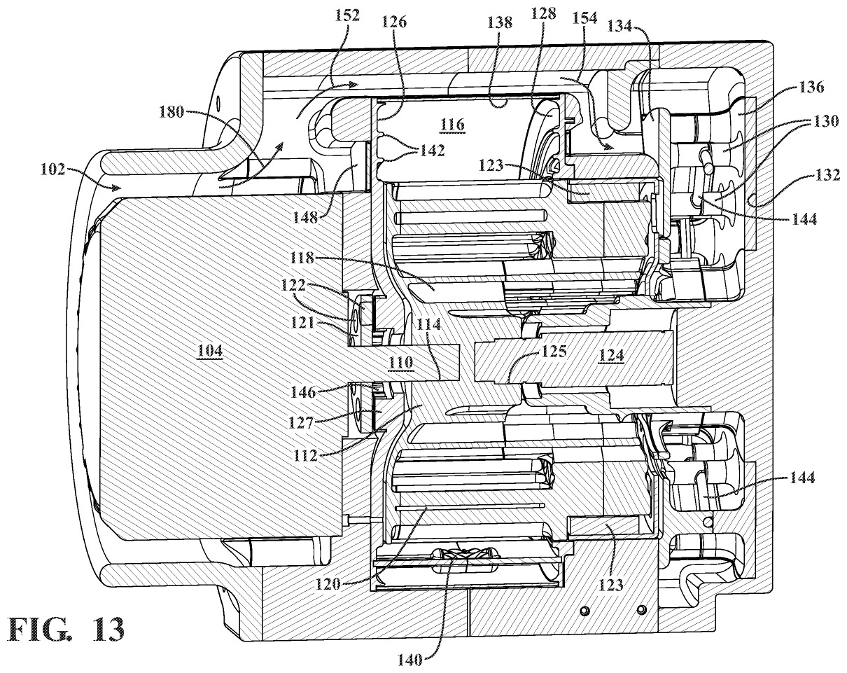

Additional magnets/electromagnets 123 are depicted mounted in an annular arrangement surrounding an end-proximate location of the drum shaped rotating component 112 and are typically fixed but can also be rotatable in other variants. A secondary support shaft 124 extends from an opposite end side wall of the insulated housing and provides bearing support to the rotating conductive component 112 via a further reinforced central aperture 125 which axial and spaced from the initial aperture 114 as shown in FIGS. 12-13. As with the initial embodiment, the magnet/electromagnet supporting plate 121 can also be constructed so as to be arranged in a fixed rotational supported fashion or can be axially displaceable between each of an extended position in which the magnets/electromagnets are disposed in proximity to the fixed inner housing support location 127 and a retracted position in which the magnets/electromagnets are displaced laterally away in the non-thermally conditioning air circulation mode.

Alternatively, or in combination to displacing laterally away from the magnets/electromagnets, it is further envisioned that magnetic shielding can be accomplished by sliding or rotating a spacer with one layer or multiple layers of one or multiple magnetic shielding materials with high magnetic permeability and with high magnetic saturation. Ferromagnetic metals such as steels or MuMetal, an industry reference material defined in Milspec 14411C. It is also envisioned that, in the instance of electromagnets, these can be deactivated or turned off in a further non-thermally conditioning air circulation mode. As previously described, the present invention further contemplates other configurations for supporting any arrangement of magnets/electromagnets within any of the insulating body or inner housing, the central interior rotating conductive component, or any position between, in order to provide the desired thermal conditioning properties.

The inner housing of the body for creating the spiral inner passageway further includes a pair of side plates 126 and 128 which are configured within a central open interior of the insulated body as shown in FIGS. 12-13. The first of these plates at 126 further integrates the reinforced central region 127 which receives the shaft 110 and provides structural bearing support for the inner opposing end of the generally drum shape profile of the rotating conductive component 112.

A plurality of thermal sink pins 130 are incorporated into an annular array arranged in proximity to an inwardly facing and annular configured end surface 132 of the body. The thermal heat sink pin array further includes a pair of spaced apart rings 134 and 136 which support therebetween the array of heat sink pins 130, with the inner ring 134 located proximate the magnets/electromagnets 123 and the outer ring 136 seated against the annular mating and inwardly facing remote end-surface 132 of the body. In operation, the array of heat sink pins 130 draw outwardly emanating heat from the core interior toward far interior end of the body (opposite the illustrated mounting location of the motor or other rotary inducing input 104 or other rotatable input) back through the walls of the plates 126/128 of the interior housing and into the core located spiral interior passageway 116, this in order to optimize redirection of thermal flow by the inner 118 and outer 120 plurality of vanes through the outlet 106.

As best again depicted in FIGS. 12-13, the spiral extending inner housing is shown in cutaway surrounding and supported the interior rotating conductive component 112 and further including an outer end cap 138 which mates with outer edges of the side plates or walls 126/128 walls. The inner housing (plates 126/128 and end cap 138) can, without limitation, be constructed of any suitable metal or alloy, ceramic or any metal-ceramic composite material or graphite or any combination of such materials which, in combination with the central rotating conductive component 112, provides any degree of thermal conductivity.

Additional features include the provision of airflow redirecting elements (at 140 in FIGS. 12-13), these including baffles incorporated into the arcuately extending inner end cap surface 138 of the inner housing defining the spiral passageway and which again operates to influence the fluid flow along the spiral passageway toward the outlet. Without limitation, the spiral airflow redirection components 140 can also be configured to provide additional electrical cogeneration capabilities. Similar to the initial embodiment, the inside surfaces of the side plates 126/128 can also include arcuate side passageway projection, see for example at 142, to further assist in maintaining continuous fluid flow redirection along the spiral extending passageway interior of the inner housing toward the outlet 106.

Similar to the initial embodiment, conventional heating elements 144 are provided, these again including such as resistor coils, electromagnetic induction components or electronic wave heating components as shown in FIGS. 12-13 and which can be integrated into the annular array of heat sink pins 130 as shown in perimeter extending fashion. In this fashion, the heating elements 144 again provide faster thermal conditioning of the conductive materials across which the fluid flow is directed. As previously described, the conventional heating elements can include any of electrical resistance, electromagnetic induction or electronic wave heating types, and are usually deactivated or turned off after an initial start-up period has passed, typically indicative of the inductive or magnetocaloric material having achieved desired thermally conditioned (heat up or cooled) properties.

Other features again include the provision of coils or other thermal electric generating components surrounding a rotating shaft for generating electricity as a further cogeneration application of the assembly. This can include rotational electric generating components shown at 146 in FIGS. 12-13 surrounding the rotating shaft for generating electricity in a cogeneration application of the assembly. Additionally or alternately, solid state thermoelectric generator devices are strategically located upon the inner housing (see at 148 in FIG. 13 as well as at 149 in the rotated view of FIG. 12) these for converting temperature differences resulting from the oscillating magnetic fields at a given frequency range into electrical energy in a cogeneration application of the assembly.

In this fashion, the intake air 102 is pre-heated within the body interior, along passageways 150, 152 and 154 depicted in each of FIGS. 12-13, and resulting from passage in proximity to the motor or other rotary inducing component 104. At this point, the main inductive heating occurs at the core interface of the rotating conductive component or plate 112 (where the magnets/electromagnets 122 are situated) relative to the surrounding inner housing plates 126/128, with the thermal conditioned flow then being directed by the vanes 118/120 of the rotating plate 112 through the forward outlet 106.

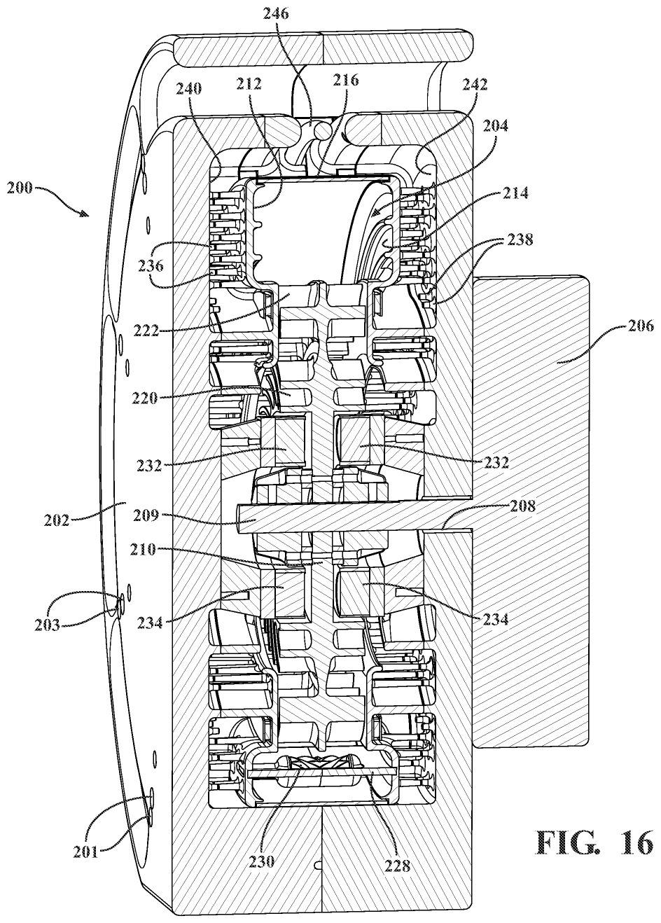

With reference now to each of FIGS. 16-19, a series of cutaway views are presented depicting variants of a magnetocaloric/magnetic or electromagnetic induction furnace/heater, magnetocaloric heat pump or like assembly, these including combinations of externally or internally supported motors or other rotary inducing inputs, as well as showing either of magnet/electromagnetic or induction coil arrangements for generating the desired magnetic induction/magnetocaloric conditioning of the air or fluid passing through the furnace/heater assemblies.

FIG. 16 is a cutaway view of a first selected one of the sub-variants of the magnetocaloric/magnetic or electromagnetic induction furnace/heater, magnetocaloric heat pump or like assembly, generally at 200 and showing an insulating outer body 202 includes any arrangement of fluid inlets (without limitation can include aperture patterns 201, 203, et. seq. depicted in the sides of the body) and a forward facing fluid outlet (this further not shown but approximated in position to the spiral passageway location depicted at 204). An inner housing is shown and includes a spiral configured interior passageway (at 204) for collecting and redirecting a fluid flow for exhaust through the forward directed outlet.

As further shown, the body can be constructed of any suitable insulating material and can exhibit without limitation a three dimensional radial shape with the curved forward facing location incorporating any of the selected inlets and outlet. An externally mounted motor or other rotary inducing input 206 is situated in proximity to a circular shaped side opening 208 in the body 202 for receiving an inwardly projecting shaft 209. As will be described in further variants, the motor or other rotary inducing input can be internally or externally mounted with respect to the assembly.

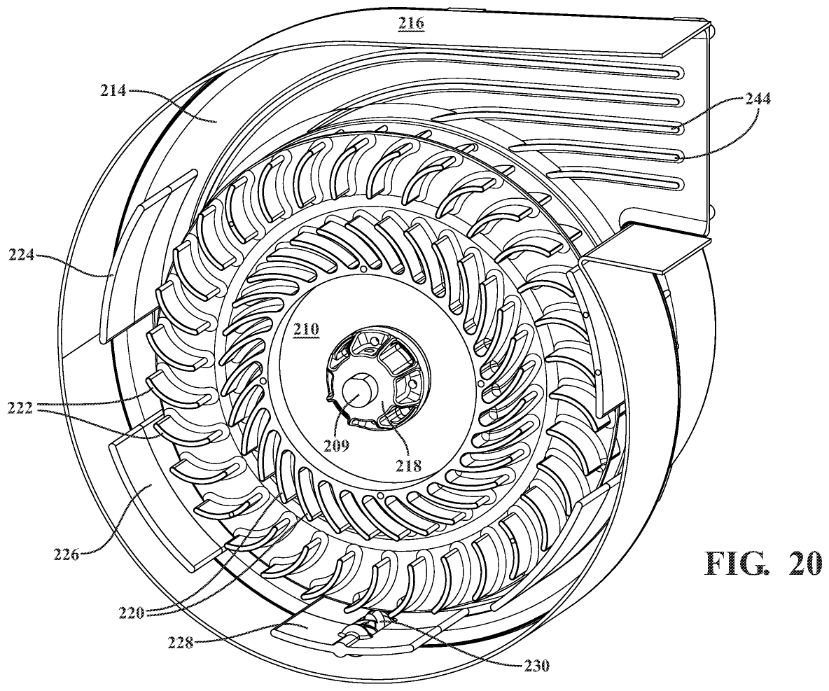

A central rotatable conductive component 210 is depicted which is actuated by the motor or other rotary inducing input 206 in rotating fashion between opposing plates 208 and 210 which define spaced apart walls of the inner housing. As further shown in the sectional perspective cutaway of FIG. 20, selected side wall 214 of the spiral passageway inner housing of any of FIGS. 16-19 is again depicted and further shows an upper and interconnected end cap 216 which extending between the spaced apart inner side walls 212 and 214 in order to enclose the interior passageway.

The rotating/redirecting component 210 can be constructed of any conductive or magnetocaloric material and includes a central reinforced aperture support location 218 (see FIG. 20) for mounting to an end location of the shaft 209 and so that the rotating component 210 is supported within the inner housing structure of the plates 212 and 214 defining the spiral configured interior passageway (again at 204) for collecting and redirecting the fluid flow between the inlet and outlet locations.

Referencing again FIGS. 16-20, the rotating conductive component 210 is typically a conductive disk-shaped component having inner 220 and outer 222 arcuate and segmented pluralities of fluid flow redirecting vanes extending from each of opposite surfaces of the component 210 and about both of inner and outer circumferences of the component. As further shown, the respective inner 220 and outer 222 radial spaced pluralities of vanes can be arranged so that their arcuate profiles are opposing one another, this assisting in baffling or slowing of the outwardly directed fluid flows in order to maximize their thermal conditioning profiles.

Also depicted are an arrangement of baffles 224 placed in the outer annular fluid chamber of the inner housing which, in operation, redirect air/fluid movement to facilitate a more balanced exhaust pattern, as well as again showing the wind generators placed in any or all of the baffles or walls of the inner housing. The baffles further serve to warm the exhaust air through any of surface or air radiation. Also shown at 230 are wind channeling components integrated into selected baffles (see as shown at 228 in each of FIGS. 16 and 20), and which can alternately be configured directly into the end cap 216. The wind channeling components operate both to channel and redirect the spiral airflow, with these components capable of being reconfigured to operate as wind generator components for providing electric power (wattage) in a cogeneration application of the present inventions.

Referring again to FIG. 16, either of magnets or electromagnets, see at 232 and 234, can be supported at any location within the body 202, either inside or outside of the inner housing and preferably in surrounding proximity to the rotating conductive component 210. The magnets/electromagnets 232/234 in one non-limiting arrangement shown are shown positioned within a stationary interior of the inner housing, on opposite side of a central-most region of the rotating conductive component 210 proximate the supporting shaft 209 and, in response to rotation of the outer component 210 in proximity to the magnets/electromagnets 232/234, results in the thermal conditioning of the fluid flow arising from the creation of the high frequency oscillating magnetic fields, with the thermally conditioned fluid flow being redirected through the outlet.

Additional variants of the present invention also contemplate the magnets/electromagnets 232/234 being reconfigured onto a separate plate and again either positioned stationary or rotatable relative to the conductive fan component 210, and this can also include relocating (although not being shown) to a separate plate or like support which can be positioned about the shaft 209 and which is displaceable between each of an extended position in which the magnets/electromagnets are disposed in proximity to the rotating conductive plate or component and a retracted position in which the magnets/electromagnets are displaced laterally away from the rotating component in a further non-thermally conditioning air circulation mode.

Alternatively, or in combination to displacing laterally away from the magnets/electromagnets, magnetic shielding can be accomplished by sliding or rotating a spacer with one layer or multiple layers of one or multiple magnetic shielding materials with high magnetic permeability and with high magnetic saturation. Ferromagnetic metals such as steels or MuMetal, an industry reference material defined in Milspec 14411C. Also, and in the instance of electromagnets, these can be deactivated or turned off in a further non-thermally conditioning air circulation mode.

The present invention further contemplates other configurations for supporting any arrangement of magnets/electromagnets within either of the inner housing, the central interior rotating conductive component, or any position between, in order to provide the desired thermal conditioning properties. This can also include other ways of shielding the magnets and which can include turning off in the instance of using electromagnets. As further previously described, electromagnetic shielding is the practice of reducing the electromagnetic field in a space by blocking the field with barriers made of conductive or magnetic materials.

Pluralities of thermal sink pins, see at 236 and 238, respectively, are incorporated into each of opposite and outer facing sides (see plates 212 and 214) of the inner housing and respectively extend to inside wall surfaces (at 240 and 242) of the body 202, this in order to draw outwardly emanating heat from the sides of the body back through the walls of the plates 212/214 and into the spiral interior passageway 204 in order to optimize redirection of thermal flow by the inner 220 and outer 222 plurality of vanes through the forward directed outlet. As further best shown, the thermal sink pins can include different sizes or configurations depending upon their location on the exterior of the side plates.

The inner housing plates 212/214 and end cap 216 can, without limitation, be constructed of any suitable metal or alloy, ceramic or any metal-ceramic composite material or graphite or any combination of such materials which, in combination with the central rotating conductive component 210, provides any degree of thermal conductivity. The inside surfaces of the side plates can also include arcuate side passageway projection, see at 244 in the cutaway of FIG. 20 associated with inner housing side plate 214, this functioning to further assist in maintaining continuous fluid flow redirection along the spiral extending passageway interior of the inner housing toward the outlet.

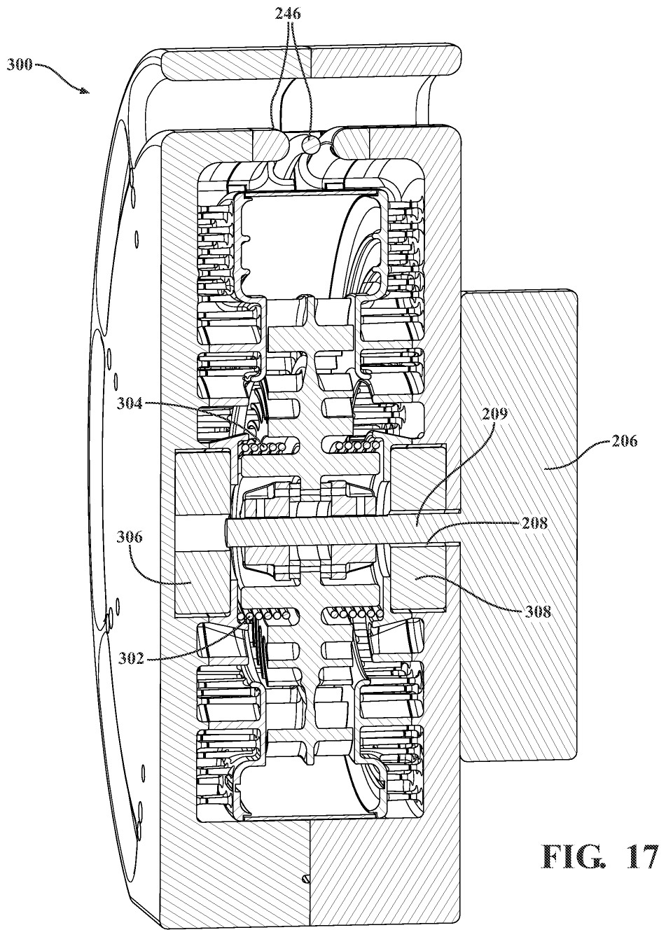

Additional features include conventional heating elements 246 (this also present in the related variants of each of FIGS. 17-19), such as resistor coils, electromagnetic induction components or electronic wave heating components as shown in each of the related variants of FIGS. 16-19 and which, in the instance of the variant of FIG. 16, can be integrated into the housing in perimeter extending fashion around the rotating plate or component 210 and the outer sandwiching housing plates 212/214, this in order to provide faster thermal conditioning of the conductive materials across which the fluid flow is directed. The conventional heating elements are usually deactivated or turned off after an initial start-up period has passed, typically indicative of the inductive or magnetocaloric material having achieved desired thermally conditioned (heat up or cooled) properties.

Other features can include the provision of coils or other thermal electric generating components, these without limitation capable of being integrated into the walls of the side plates 212/214 surrounding the rotating shaft 209 for generating electricity as a further cogeneration application of the assembly. The solid-state thermoelectric generator devices can also be located upon the inner housing at any other suitable location for converting temperature differences resulting from the oscillating magnetic fields at a given frequency range into electrical energy in a desired cogeneration application of the assembly, with the electric power (wattage) created also capable of being inputted to the motor or other rotary inducing input 206 for achieving decreased electrical operating costs.

In this fashion, intake air is pre-heated within the body interior before being directed in proximity to the interface between the rotating conductive component 210 and the proximate magnets/electromagnets 232/234 where the main inductive heating occurs, and with the thermal conditioned flow then being directed by the vanes 220/222 of the rotating plate 210 through the outlet.

Without limitation, the configuration and material selection for each of the plates 212/214 and end cap are such that they can be selected from any conductive materials which can include varying patterns of materials, bi-materials or multi-materials designs, such including any of metals or alloys, ceramics or any metal ceramic composite materials with ferromagnetic, ferromagnetic, antiferromagnetic, paramagnetic or diamagnetic properties. As understood, the plates possess properties necessary to generate adequate oscillating magnetic fields for inducing magnetic heating, such again resulting from the ability to either maintain or switch the magnet polarity at a sufficiently high rate in order for the generated friction to create the desired heat/cold profile

Without limitation, conductive material(s) incorporated into the assembly can include varying patterns of materials, bi-materials or multi-material designs, such including any of metals or alloys, ceramics or any metal ceramic composite materials with ferromagnetic, ferrimagnetic, antiferromagnetic, paramagnetic or diamagnetic properties and, as understood, do not generate magnetic fields but are based on electromagnetic or magnetic induction such that they create eddy currents to allow for the frictional generation of heat in proximity to the interface between the rotating central component and the surrounding plates and end cap defining the inner spiral extending passageway.

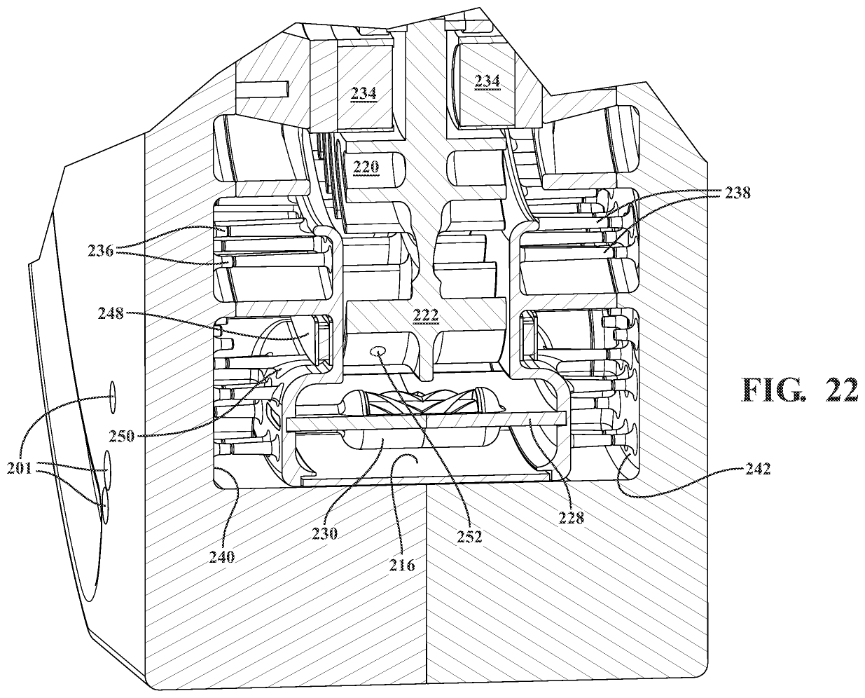

FIG. 22 is an enlarged lower partial cutaway perspective of the assembly in FIG. 16 and better depicting the features of air/fluid intake 250 and exhaust 252 ports configured into the inner housing in combination with any variant of the thermoelectric cogeneration components, as previously shown at 248, and rotary air/fluid flow generating/redirection components 230 for redirecting electric power (wattage) produced by the generators into the input electric power (wattage) for driving the motor or other rotary inducing input in order to reduce operating costs for the overall assembly. Also shown are the thermal sink pins 236/238 as well as the lower located pair of magnets/electromagnets 234 located in inward radial proximity to the inner most plurality of fluid redirection vanes 220.

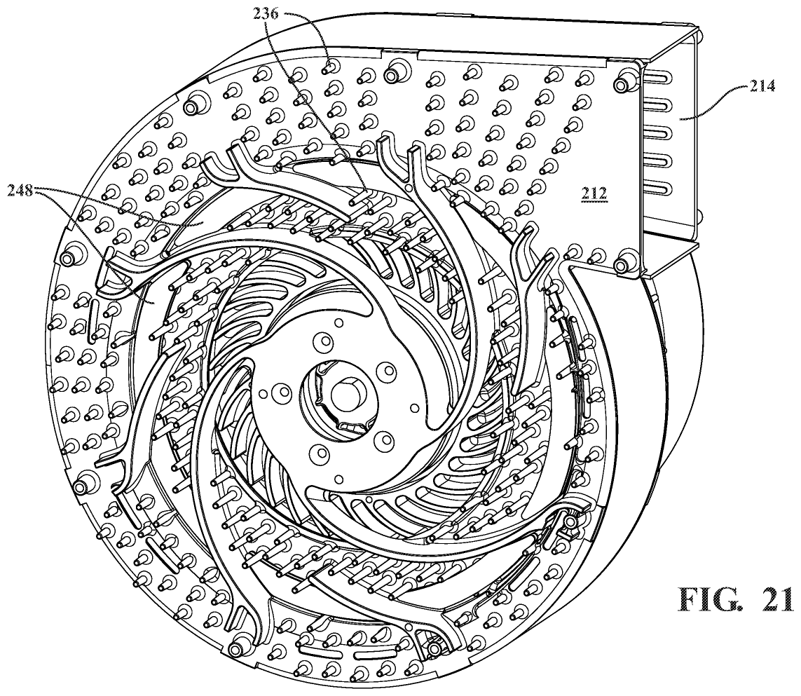

Referring now to FIG. 17, presented is a variant 300 of the assembly of FIG. 16 and substituting the magnets/electromagnets in favor of induction coils 302/304 and coil controllers 306/308 for providing additional electrical cogeneration capabilities along with thermal conditioning the fluid through the assembly via the properties of induction heating which involves passing a current through the coils to create an oscillating magnetic field to generate eddy currents or Joule heating. The coils 302/304 are generally approximate in location to the magnets/electromagnets of FIG. 16 to create electric induction heating. The remaining features are identical to that previously shown and described in FIGS. 16 and 20-22 and are again illustrated without further explanation.

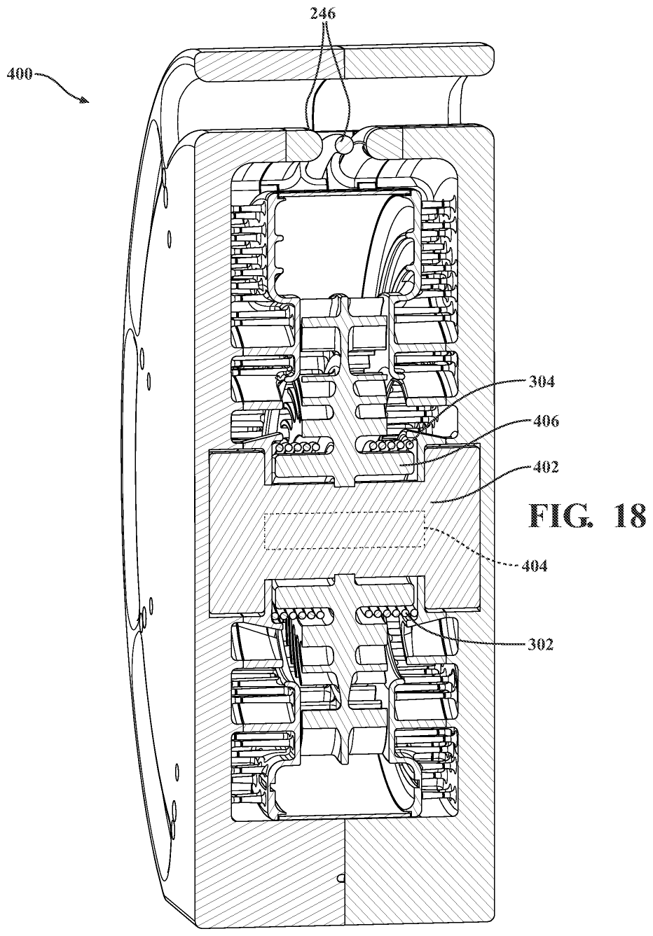

FIG. 18 illustrates a further subset variant 400 of FIG. 17 and by which an internal motor or other rotary inducing input construction 402 substitutes for the external motor or other rotary inducing input 206, this provided in combination with the induction heating coils 302/304 and associated controllers. The motor or other rotary inducing input includes an integrated central shaft (represented in phantom 404) which supports and rotates a conductive component 406 (see as similar to 210 in FIG. 20) in proximity to the coils 302/304, which are stationary supported within the body.

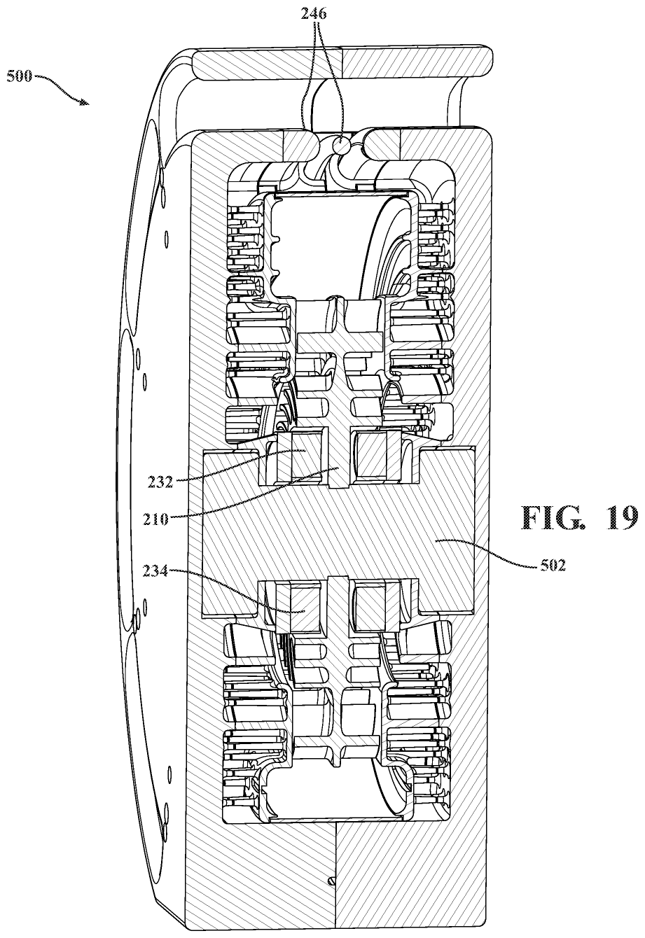

Finally, FIG. 19 presents an internal motor or other rotary inducing input reconfiguration 500 of the assembly of FIG. 16 with the interior positioned magnets/electromagnets 232/234 again utilized in combination with a redesigned internal motor or other rotary inducing input 502. An internal rotor component (not shown) of the motor or other rotary inducing input 502 can include a central-most shaft for rotating the conductive plate (again shown at 210) relative to the arrangement of magnets/electromagnets 232/234, the latter being typically stationary supported however also rotatable in further potential embodiments.

As previously described, other and additional envisioned applications can include adapting the present technology for use in magnetocaloric heat pump (MHG) applications, such utilizing a magnetocaloric effect (MCE) provide either of heating or cooling properties resulting from the magnetization (heat) or demagnetization (cold) cycles. The goal in such applications is to achieve a coefficient of performance (defined as a ratio of useful heating or cooling provided to work required) which is greater than 1.0. In such an application, the system operates to convert work to heat as well as additionally pumping heat from a heat source to where the heat is required (and factoring in all power consuming auxiliaries). As is further known in the relevant technical art, increasing the COP (such as potentially to a range of 2.0-3.5 or upwards) further results in significantly reduced operating costs in relation to the relatively small input electrical cost required for rotating the conductive plate(s) relative to the magnetic plate(s). Such considerations were generally limited to unimplementable ideas related to cooling operations. Magnetic refrigeration techniques result in a cooling technology based on the magnetocaloric effect and which can be used to attain extremely low temperatures within ranges used in common refrigerators, such as without limitation in order to reconfigure the present system as a fluid chiller, air cooler, active magnetic regenerator or air conditioner.

As is further known in the relevant technical art, the magnetocaloric effect is a magneto-thermodynamic phenomenon in which a temperature change of a suitable material is again caused by exposing the material to a changing magnetic field, such being further known by low temperature physicists as adiabatic (defined as occurring without gain or loss of heat) demagnetization. In that part of the refrigeration process, a decrease in the strength of an externally applied magnetic field allows the magnetic domains of a magnetocaloric material to become disoriented from the magnetic field by the agitating action of the thermal energy (phonons) present in the material.

If the material is isolated so that no energy is allowed to (re)migrate into the material during this time, (i.e., again the adiabatic process) the temperature drops as the domains absorb the thermal energy to perform their reorientation. The randomization of the domains occurs in a similar fashion to the randomization at the Curie temperature of a ferromagnetic, ferrimagnetic, antiferromagnetic, paramagnetic or diamagnetic material, except that magnetic dipoles overcome a decreasing external magnetic field while energy remains constant, instead of magnetic domains being disrupted from internal ferromagnetism, ferrimagnetism, antiferromagnetism, (or either of paramagnetism/diamagnetism) as energy is added. Applications of this technology can include, in one non-limited application, the ability to heat a suitable alloy arranged inside of a magnetic field as is known in the relevant technical art, causing it to lose thermal energy to the surrounding environment which then exits the field cooler than when it entered.

Other envisioned applications include the ability to generate heat for conditioning any fluid (not limited to air or water) utilizing either individually or in combination rare earth magnets placed into an oscillating magnetic field at a given frequency range as well as static electromagnetic field source systems including such as energized electromagnet assemblies which, in specific instances, can be combined together within a suitable assembly not limited to that described and illustrated herein and for any type of electric induction, electromagnetic and magnetic induction or magnetocaloric application. It is further envisioned that the present assembly can be applied to any material which is magnetized, such including any of diamagnetic, paramagnetic, and ferromagnetic, ferrimagnetic or antiferromagnetic materials without exemption also referred to as magnetocaloric materials (MEMs).

Additional factors include the ability to reconfigure the assembly so that the frictionally heated fluid existing between the overlapping rotating magnetic and stationary fluid communicating conductive plates may also include the provision of additional fluid mediums (both gaseous and liquid state) for better converting the heat or cooling configurations disclosed herein. Other envisioned applications can include the provision of capacitive and resistance (ohmic power loss) designs applicable to all materials/different configurations as disclosed herein.

The present invention also envisions, in addition to the assembly as shown and described, the provision of any suitable programmable or software support mechanism, such as including a variety of operational modes. Such can include an Energy Efficiency Mode: step threshold function at highest COP (at established motor or other rotary inducing input rpm) vs Progressive Control Mode: ramp-up curve at different rpm/COPs).

Other heating/cooling adjustment variables can involve modifying the degree of magnetic friction created, such as by varying the distance between the conductive fluid circulating disk packages and alternating arranged magnetic/electromagnetic plates. A further variable can include limiting the exposure of the conductive fluid (gas, liquid, etc.,) to the conductive component/linearly spaced disk packages, such that a no flow condition may result in raising the temperature (and which can be controllable for certain periods of time).

As is further generally understood in the technical art, temperature is limited to Curie temperature, with magnetic properties associated with losses above this temperature. Accordingly, rare earth magnets, including such as neodymium magnets, can achieve temperature ranges upwards of 900° C. to 1000° C.

Ferromagnetic, ferrimagnetic, antiferromagnetic, paramagnetic or diamagnetic materials, such as again which can be integrated into the conductive plates, can include any of Iron (Fe) having a Curie temperature of 1043K (degrees Kelvin), Cobalt (Co) having a Curie temperature of 1400K, Nickel (Ni) having a Curie temperatures of 627K and Gadolinium (Gd) having a Curie temperature of 292K.

According to these teachings, Curie point, also called Curie Temperature, defines a temperature at which certain magnetic materials undergo a sharp change in their magnetic properties. In the case of rocks and minerals, remanent magnetism appears below the Curie point—about 570° C. (1,060° F.) for the common magnetic mineral magnetite. Below the Curie point—by non-limiting example, 770° C. (1,418° F.) for iron—atoms that behave as tiny magnets spontaneously align themselves in certain magnetic materials.

In ferromagnetic materials, such as pure iron, the atomic magnets are oriented within each microscopic region (domain) in the same direction, so that their magnetic fields reinforce each other. In antiferromagnetic materials, atomic magnets alternate in opposite directions, so that their magnetic fields cancel each other. In ferrimagnetic materials, the spontaneous arrangement is a combination of both patterns, usually involving two different magnetic atoms, so that only partial reinforcement of magnetic fields occurs.

Given the above, raising the temperature to the Curie point for any of the materials in these three classes entirely disrupts the various spontaneous arrangements, and only a weak kind of more general magnetic behavior, called paramagnetism, remains. As is further known, one of the highest Curie points is 1,121° C. (2,050° F.) for cobalt. Temperature increases above the Curie point produce roughly similar patterns of decreasing paramagnetism in all three classes of materials such that, when these materials are cooled below their Curie points, magnetic atoms spontaneously realign so that the ferromagnetism, antiferromagnetism, or ferrimagnetism revives. As is further known, the antiferromagnetic Curie point is also referenced as the Neel temperature.

Other factors or variable controlling the temperature output can include the strength of the magnets/electromagnets which are incorporated into the magnet/electromagnet carrier or magnetic/electromagnetic plates, such as again by selected rare earth magnets having varying properties or, alternatively, by adjusting the factors associated with the use of electromagnets including an amount of current through the coils, adjusting the core ferromagnetic properties (again though material selection) or by adjusting the cold winding density around the associated core.

Other temperature adjustment variables can include modifying the size, number, location and orientation of the assemblies (elongated and plural magnet/electromagnet and alternative conductive plates). Multiple units or assemblies can also be stacked, tiered or otherwise ganged in order to multiply a given volume of conditioned fluid which is produced.

Additional variables can include varying the designing of the conductive disk packages, such as not limited varying a thickness, positioning or configuration of a blade or other fluid flow redirecting profile integrated into the conductive plates, as well as utilizing the varying material properties associated with different metals or alloys, such including ferromagnetic, ferrimagnetic, antiferromagnetic, paramagnetic and diamagnetic properties.

Having described my invention, other and additional preferred embodiments will become apparent to those skilled in the art to which it pertains, and without deviating from the scope of the appended claims. The detailed description and drawings are further understood to be supportive of the disclosure, the scope of which being defined by the claims. While some of the best modes and other embodiments for carrying out the claimed teachings have been described in detail, various alternative designs and embodiments exist for practicing the disclosure defined in the appended claims.

The foregoing disclosure is further understood as not intended to limit the present disclosure to the precise forms or particular fields of use disclosed. As such, it is contemplated that various alternate embodiments and/or modifications to the present disclosure, whether explicitly described or implied herein, are possible in light of the disclosure. Having thus described embodiments of the present disclosure, a person of ordinary skill in the art will recognize that changes may be made in form and detail without departing from the scope of the present disclosure. Thus, the present disclosure is limited only by the claims.

In the foregoing specification, the disclosure has been described with reference to specific embodiments. However, as one skilled in the art will appreciate, various embodiments disclosed herein can be modified or otherwise implemented in various other ways without departing from the spirit and scope of the disclosure. Accordingly, this description is to be considered as illustrative and is for the purpose of teaching those skilled in the art the manner of making and using various embodiments of the disclosure. It is to be understood that the forms of disclosure herein shown and described are to be taken as representative embodiments. Equivalent elements, materials, processes or steps may be substituted for those representatively illustrated and described herein. Moreover, certain features of the disclosure may be utilized independently of the use of other features, all as would be apparent to one skilled in the art after having the benefit of this description of the disclosure. Expressions such as “including”, “comprising”, “incorporating”, “consisting of”, “have”, “is” used to describe and claim the present disclosure are intended to be construed in a non-exclusive manner, namely allowing for items, components or elements not explicitly described also to be present. Reference to the singular is also to be construed to relate to the plural.

Further, various embodiments disclosed herein are to be taken in the illustrative and explanatory sense, and should in no way be construed as limiting of the present disclosure. All joinder references (e.g., attached, affixed, coupled, connected, and the like) are only used to aid the reader's understanding of the present disclosure, and may not create limitations, particularly as to the position, orientation, or use of the systems and/or methods disclosed herein. Therefore, joinder references, if any, are to be construed broadly. Moreover, such joinder references do not necessarily infer that two elements are directly connected to each other.

Additionally, all numerical terms, such as, but not limited to, “first”, “second”, “third”, “primary”, “secondary”, “main” or any other ordinary and/or numerical terms, should also be taken only as identifiers, to assist the reader's understanding of the various elements, embodiments, variations and/or modifications of the present disclosure, and may not create any limitations, particularly as to the order, or preference, of any element, embodiment, variation and/or modification relative to, or over, another element, embodiment, variation and/or modification.

It will also be appreciated that one or more of the elements depicted in the drawings/figures can also be implemented in a more separated or integrated manner, or even removed or rendered as inoperable in certain cases, as is useful in accordance with a particular application. Additionally, any signal hatches in the drawings/figures should be considered only as exemplary, and not limiting, unless otherwise specifically specified.

I claim:

1. A fluid conditioning assembly, comprising:
a body constructed of an insulating material;
an inner housing within said body defining a spiral passageway in communication with an inlet for redirecting a fluid flow through an outlet;
a shaft extending within said body and rotatably supporting a conductive and fluid redirecting component positioned within said inner housing; and
at least one magnet, electromagnet or induction coil positioned within said body in proximity to said inner housing, rotation of the conductive component relative to said magnets/electromagnets/coils causing thermal conditioning of the fluid flow from creation of oscillating magnetic fields at a given frequency range, the thermally conditioned fluid flow being redirected through said outlet.

2. The assembly of claim 1, said fluid redirecting component further comprising a magnetocaloric or thermally conductive material.

3. The assembly of claim 1, said fluid redirecting component further comprising a disk-shaped element having a first inner plurality of circumferentially arrayed vanes and a second outer plurality of circumferentially arrayed vanes.

4. The assembly of claim 1, said inlet further comprising multiple inlet locations configured along at least one of a side or forward facing surface of said body.

5. The assembly of claim 1, further comprising said outlet configured on a forward facing surface of said body.

6. The assembly of claim 1, further comprising a motor or other rotary inducing input for driving said shaft.

7. The system as described in claim 6, further comprising said motor or other rotary inducing input incorporated into said body.

8. The assembly of claim 1, further comprising thermal sink pins incorporated into at least one of opposite and outer facing sides of said inner housing and extending to inside wall surfaces of said body in order to draw outwardly emanating heat from the sides of the body interior, through the walls of said inside housing and toward its spiral extending interior.

9. The assembly of claim 1, further comprising airflow redirecting elements incorporated into an arcuately extending inner end cap of the inner housing defining the spiral passageway.

10. The assembly as described in claim 1, further comprising one or more heating elements integrated into said body surrounding said inner housing for assisting an initial heat up of said conductive material.

11. The assembly of claim 10, said conventional heating elements further comprising any of a resistor coil, electromagnetic induction component or electronic wave heating component.

12. The assembly of claim 10, further comprising a controller for deactivating said conventional element after a start-up period of time once the thermally conditioned air or fluid has reached a threshold temperature.

13. The assembly of claim 1, further comprising rotational wind channeling or electric generating components surrounding said rotating shaft for generating electricity in a cogeneration application of the assembly.

14. The assembly of claim 1, further comprising solid state thermoelectric generator devices located upon said inner housing for converting temperature differences resulting from said oscillating magnetic fields into electrical energy in a cogeneration application of the assembly.

15. The system as described in claim 1, said inner housing further comprising at least one of a metal, a metal alloy, a ceramic, a metal-ceramic composite material, a graphite or any combination of such conductive materials.

16. The system as described in claim 1, further comprising baffles supported within an outer perimeter of said inner housing surrounding said rotating and fluid redirecting component.

17. The assembly of claim 9, further comprising said airflow redirection elements providing optional cogeneration electrical generating capabilities and including rotational electric generating components surrounding said rotating shaft.

18. A fluid conditioning assembly, comprising:
a body constructed of an insulating material;
an inner housing within said body defining a spiral passageway in communication with an inlet for redirecting a fluid flow through an outlet;
a shaft extending within said body and rotatably supporting a conductive and fluid redirecting plate positioned within said inner housing;
said fluid redirecting component further including a magnetocaloric or thermally conductive material constructed as a disk-shaped element having a first inner plurality of circumferentially arrayed vanes and a second outer plurality of circumferentially arrayed vanes;
one or more conventional heating elements integrated into said body surrounding said inner housing for assisting initial heat up of said conductive material;
at least one of magnets or electromagnets supported at one or more locations within said body in proximity to said rotating conductive component and said inner housing, a magnetic flux resulting from rotation of the fluid redirecting component relative said magnets/electromagnets for generating inductive heating resulting in thermal conditioning of the fluid flow via creation of oscillating magnetic fields at a given frequency range, the thermally conditioned fluid flow being redirected through said outlet; and
thermal sink pins incorporated into each of opposite and outer facing sides of said inner housing and extending to inside wall surfaces of said body in order to draw outwardly emanating heat from the sides of the body interior, through the walls of said inside housing and toward its spiral extending interior.

19. A fluid conditioning assembly, comprising:
a body constructed of an insulating material;
an inner housing within said body defining a spiral passageway in communication with an inlet for redirecting a fluid flow through an outlet;
a first drive shaft extending within said body and rotatably supporting a drum shaped conductive and fluid redirecting component positioned within said inner housing and including a magneto-caloric or thermally conductive material;
a secondary support shaft extending from an opposite end of said body in axial arrangement with said first drive shaft for providing bearing support to said drum shaped rotating conductive and fluid redirecting component; and
at least one magnet or electromagnet positioned within said body in proximity to said inner housing or drum shaped rotating conductive component, a magnetic flux resulting from rotation of the fluid redirecting component relative said magnets/electromagnets for generating inductive heating resulting in thermal conditioning of the fluid flow via creation of oscillating magnetic fields at a given frequency range, the thermally conditioned fluid flow being redirected through said outlet.

20. The assembly of claim 19, said drum shaped fluid redirecting component further comprising a first inner plurality of circumferentially arrayed vanes and a second outer plurality of circumferentially arrayed vanes.
